(19) United States
(12) Patent Application Publication
(10) Pub. No.: US 2011/0168263 A1
(43) Pub. Date: Jul. 14, 2011

(54) DESIGN OF HIGHER EFFICIENCY SILICON SOLAR CELLS

(75) Inventors: Steven G. Louie, Berkeley, CA (US); Marvin L. Cohen, Piedmont, CA (US)

(73) Assignee: The Regents of the University of California, Oakland, CA (US)

(21) Appl. No.: 13/119,114

(22) PCT Filed: Sep. 17, 2009
(86) PCT No.: PCT/US09/57274

§ 371 Date: Mar. 15, 2011

Related U.S. Application Data
(60) Provisional application No. 61/098,145, filed on Sep. 18, 2008.

(51) Int. Cl. H01L 31/0264; H01L 31/0248; H01L 31/18

(52) U.S. Cl. 136/261; 438/57; 257/E31.002

(57) ABSTRACT

Higher efficiency, lower cost silicon based solar cells are provided by modifying the absorption coefficient of Silicon so that it strongly overlaps with the solar spectrum. In one embodiment this is achieved by co doping of the silicon with appropriate impurities. In another embodiment it is achieved by modifying the structure of silicon whereby a portion is converted into Silicon XII having the R8 structure.

### CROSS REFERENCE TO RELATED CASES

This application claims priority to PCT patent Application PCT/US2009/057274, filed Sep. 17, 2009, which in turn claimed priority to Provisional U.S. Patent Application Ser. No. 61/098,145 filed Sep. 18, 2008, entitled Design of Higher Efficiency Silicon Solar Cells, the contents of which applications are incorporated herein by reference, as if fully set forth in their entirety.

### STATEMENT OF GOVERNMENTAL SUPPORT

The invention described and claimed herein was made in part utilizing funds supplied by the U.S. Department of Energy under Contract No. DE-AC02-05CH11231, and the National Science Foundation under grant number DMR07-05941. The government has certain rights in this invention.

### BACKGROUND OF THE INVENTION

1. Field of the Invention

This invention relates generally to photovoltaic cells, and more particularly to silicon based photo voltaic cells of enhanced efficiency.

2. Background of the Invention

The vast majority of the photovoltaic market is based on crystalline or polycrystalline Si solar cells, with the cubic diamond phase of Si by far the most commonly studied. Thus, any improvement, however incremental, on their efficiency or cost of production would have a significant impact. Current efforts along these directions are mostly focused on the use of new designs together with lower-grade materials to reduce production costs and/or the use of band gap engineering and improved materials (e.g., better carrier mobilities) to boost efficiency. However, an un-explored idea is that the efficiency of a solar cell in generating electron and hole carriers is not only dependent on its band gap but also on its frequency-dependent photo-absorption coefficient, which is related to the electron-hole pair wavefunction at the energy of the incoming photon. A large photo-absorption coefficient at frequencies corresponding to the range of the peak in the solar spectrum would greatly enhance the production of electron-hole pairs for a given thickness of the material, resulting in improved efficiency (higher yield) and lower cost (thinner films and less demanding carrier mobilities).

### BRIEF SUMMARY OF THE INVENTION

The invention described herein produces higher efficiency and lower cost Si solar cells by modifying the absorption coefficient of Si so that it strongly overlaps with the solar spectrum. According to one embodiment of the invention, a computation and modeling approach is used to search for appropriately modified Si to enhance solar absorption for photovoltaic applications. More specifically one approach to improving the absorption properties of the silicon in the region of the solar spectrum is by changing the crystal structure of the silicon. Another approach is by using defects and dopants. The ultimate goal being to maximally harvest the sun's power with minimal production cost for the materials of the solar cell.

The gain in efficiency detailed in the embodiments below described was achieved by wavefunction engineering through co-doping of appropriate impurities and structural modifications. By increasing efficiency, the thickness of the silicon used in the solar cell may also be significantly reduced, resulting not only in lower costs, but in higher outputs due to a reduction in losses that present with thicker silicon cells.

### BRIEF DESCRIPTION OF THE DRAWINGS

FIG. 1 is a plot of solar spectral irradiance vs. photon energy (source of data: http://rredc.nrel.gov/solar/spectra/am1.5/).

FIG. 2 is a plot of measured and calculated ε₂(ω) values of silicon.

FIG. 3 upper panel is a plot of solar flux. FIG. 3 lower panel is a schematic representation of changes in the silicon absorption that can be achieved through dopants and/or structural modifications.

FIG. 4 is a plot of absorbed energy flux as a function of sample thickness for crystalline Si and Si co-doped with boron and arsenic.

FIG. 5 is a plot of absorbed energy flux as a function of sample thickness for crystalline Si and Si having the R8 structure.

### DETAILED DESCRIPTION OF THE INVENTION

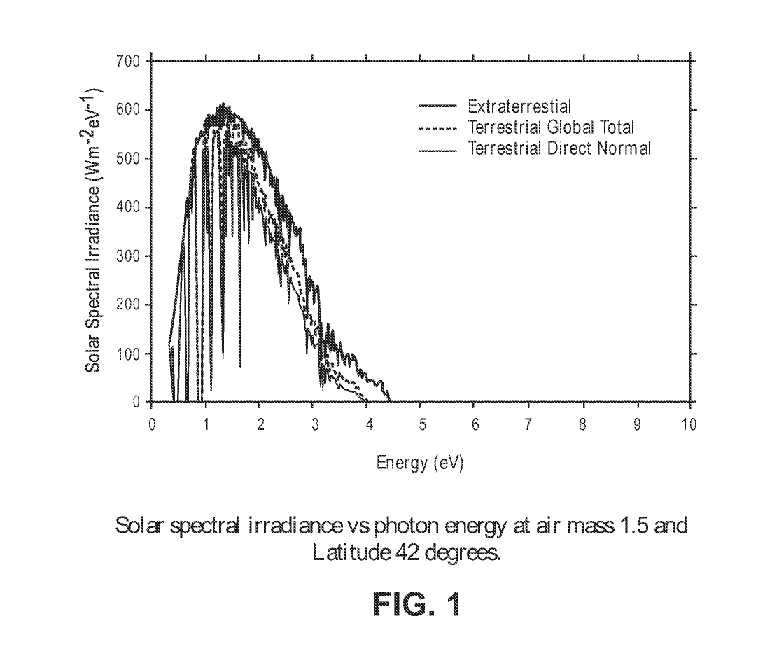

FIG. 1 shows the solar flux spectrum I(ω), the power from the sun incident on earth. Letting α(ω) be the photo-absorption coefficient of a given material, we consider only direct absorption, i.e., no phonon-assisted processes, since these higher order processes contribute very little in small thickness samples. We need to optimize the total power P absorbed for a given film thickness L, the total power P calculated according to the following formula:

$$P ( L ) = {\int }_{0}^{∞} [ 1 - exp ( - a ( ω ) L ) ] I ( ω ) d ω \qquad ( 1 )$$

The absorption coefficient α(ω) is a material-dependent quantity and related to the imaginary part of the dielectric function ε₂(ω). (α=ε₂ω/nc where n is the reflective index.) Note that P, for small L, is quite sensitive to the absorption coefficient since α(ω) goes in an exponential factor.

To increase P(L) for small L, therefore the efficiency of a thin Si or other solar cell, we would like to have α(ω) as large as possible over the range of the solar spectrum shown in FIG. 1. However, because of the f-sum rule, α(ω) cannot be arbitrarily large and it must satisfy certain physical constraints—that is, if α(ω) is to increase in one frequency range, its must decrease in another frequency range. Also, other considerations such as power output and heat generation limit the usefulness of the very low and very high frequency photons. On the other hand, we could modify Si to make α(ω) larger where I(ω) is large. Since α(ω), or equivalently ε₂(ω), depends strongly on the wavefunction of the electron-hole pair (excitonic states) generated, this now becomes a program of wavefunction engineering instead of just band gap engineering.

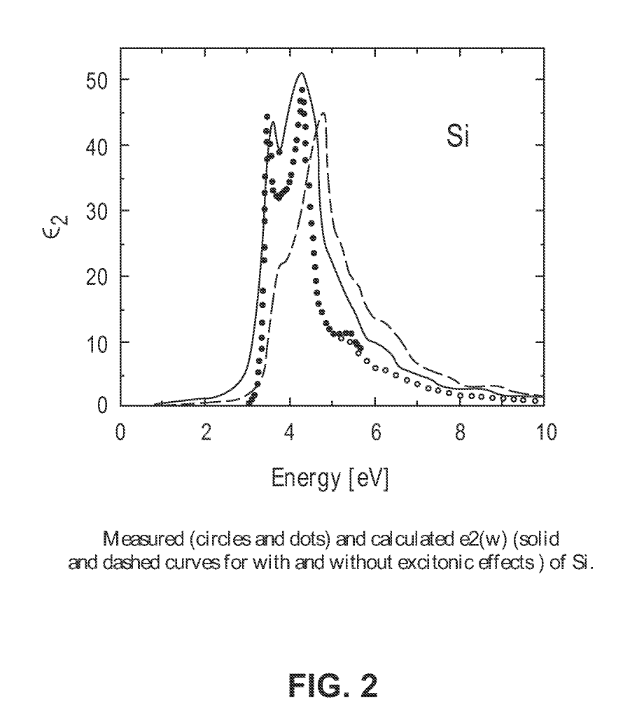

This is a highly constrained optimization problem, involving constraints of physics laws, materials problems, and economical cost. But since P(L) is a sensitive function of α(ω), we have been able to improve on the absorption efficiency of thin crystalline Si by modifying it appropriately with impurities, structural modifications, surface coatings, etc. For optical response calculation, one must put in the crucial effects of electron-hole (or excitonic) interactions. Theoretical advances, pioneered by our group, now allow us to calculate the absorption spectrum of any semiconductor, with and without dopants. FIG. 2 illustrates the power of our current methodology.

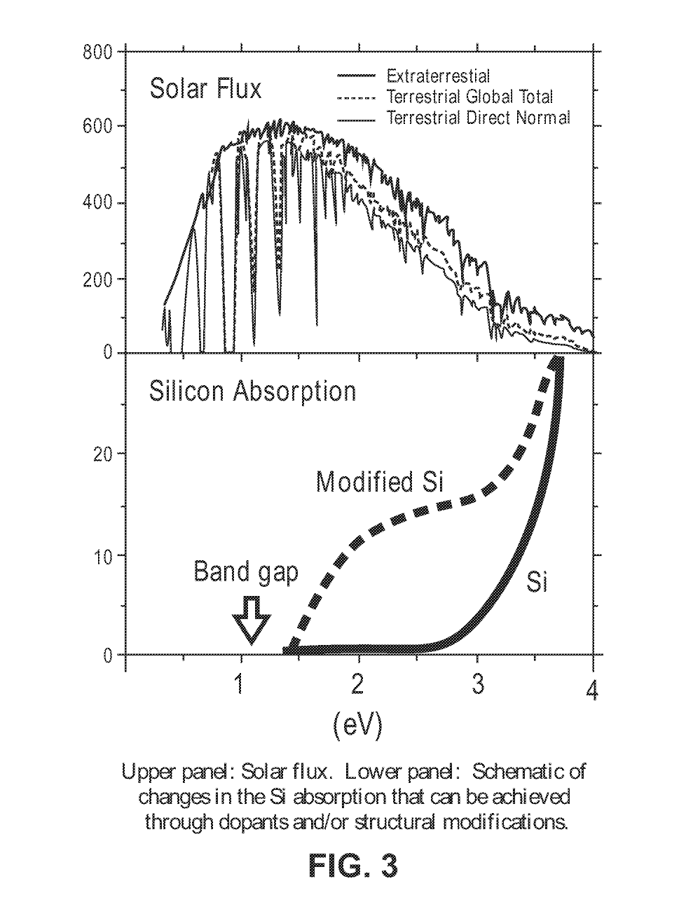

It shows that 1) theory is capable of predicting accurately ε₂(ω) and therefore the direct absorption coefficient, and 2) electron-hole interaction or excitonic effects are very important in determining the frequency dependent of the absorption strength. We see that if excitonic effects are neglected, the optical strength can be off by a factor of 2 and the spectral peaks are at the incorrect energies. By monitoring the changes in ε₂(ω) by introducing changes to Si, we are able to theoretically find the appropriate changes needed to enhance P(L) discussed above. By comparing the solar spectrum in FIG. 1 with the Si spectrum in FIG. 2, we see that Si is far from optimal in capturing the solar photons. FIG. 3 schematically illustrates the improvements in efficiency obtainable according to the approaches described herein.

### EXAMPLES

We now give below two illustrations showing that dramatic changes can be induced in the optical properties of Si structures using our concept and approach. In one example specific dopants are incorporated into the Si structure, in another the structure of the silicon itself is modified.

### Silicon Co-Doped With Boron And Arsenic Impurities

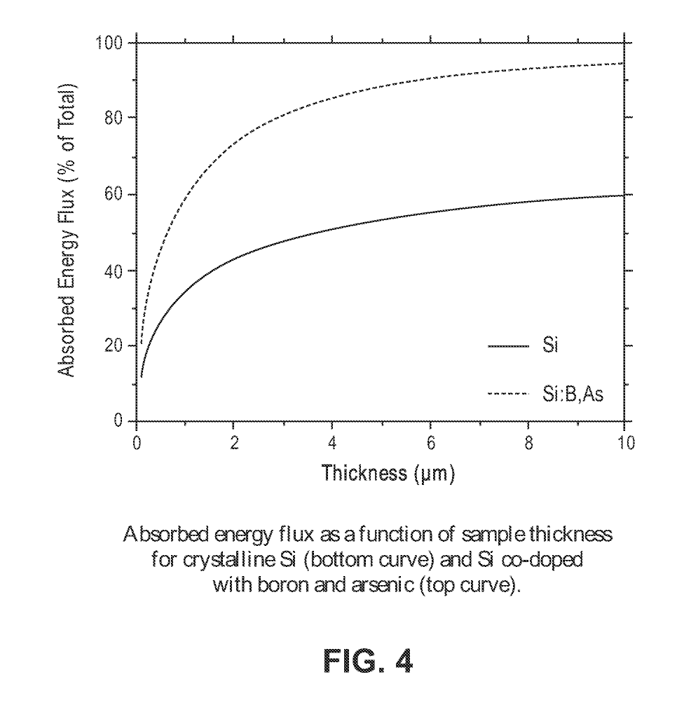

Boron (B) and arsenic (As) atoms are introduced in equal amount as substitutional impurities in Si at a few percents level. These dopants modify the absorption spectrum of Si in the way illustrated in the lower panel of FIG. 3. The increase in the absorption coefficient in the solar flux spectrum range greatly enhances the creation of electron-hole pairs in the system. Using Eq. 1, the absorbed energy flux in percentage of the total flux may be calculated and compared to conventional Si. We see from FIG. 4 that there is a dramatic increase in the efficiency of photon absorption for the B/As co-doped Si. The amount of light absorbed is nearly doubled for films in the range of a few microns thick

### Silicon In the R8 Structure

Similarly, the optical properties of silicon also can be significantly changed when its atomic structure is modified from its normal diamond structure. One meta-stable form of silicon is in the so-called R8 structure (named because of its rhombohedral unit cell structure, containing eight atoms, and also known as Si-XII). R8 Si is made experimentally by applying pressure to ordinarily silicon. More particularly, as reported in the paper Ab initio study of the Optical Properties of Si-XII, cited at paragraph [0021] below, which paper is incorporated herein by reference, silicon in the R8 structure can be formed upon decompression from high pressure metallic β-Sn phase at approximately 10 GPa. The R8 structure remains the dominant phase until approximately 2 GPa when the BC8 (Si-III) structure begins to form. The presence of Si R8 has also been reported in nano indentation experiments performed on silicon wafers by S. Ruffell, J. E. Bradby, N. Fujisawa, and J. S. Williams (J. Appl. Phys. 101, 0383531 (2007). For a further discussion of Silicon R8, see Ab Initio Study of Silicon in the R8 Phase, B. G. Pfrommer, M. Cote, S. G. Louie, and M. L. Cohen, Physical Review B, volume 56, Number 11, 6662-6667, 15 Sep. 1997, as well as Ab Initio Survey of the Electronic Structure of Tetrahedrally Bonded Phases of Silicon, B. D. Malone, J. D. Sau, and M. L. Cohen, Phys. Rev. B 78, 035210 (29 Jul. 2008), both of which articles are incorporated herein by reference.

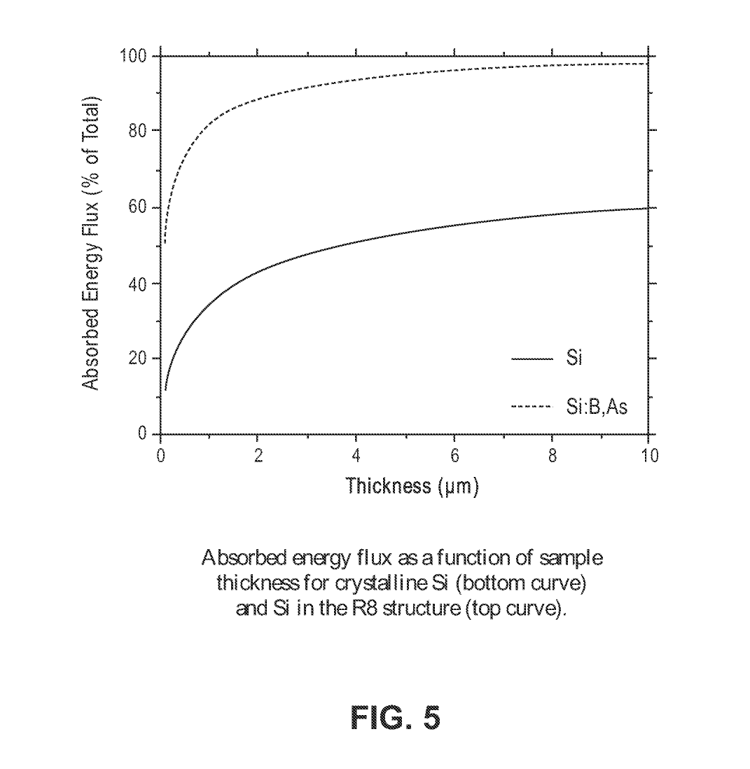

FIG. 5 depicts the change in absorption efficiency for Si R8 as a function of sample thickness. Thus, it can be seen, that by using this form of silicon or by embedding this form of meta-stable structure into bulk Si, for example by pressure induced crystallization (i.e. structural) changes using indenters (such as diamond tipped indenters more typically used in conjunction with hardness measurements. See S. Ruffell, et al., infra), the optical response can be altered to yield more efficient solar production of electron hole pairs for a given sample thickness.

A more complete discussion of this approach as it relates to R8 Silicon appears in the unpublished article entitled Ab initio study of the Optical Properties of Si-XII, B. D. Malone, J. D. Sau and M. L. Cohen, a copy of which was attached to our provisional application, and the contents of which article were fully incorporated therein by reference, said article published as of Oct. 17, 2008 in Physical Review B 78, 161202(R) (2008).

Having demonstrated that Si-XII has a larger absorption coefficient at the lower energies, which more nearly overlap with the solar spectrum than other forms of silicon, such allows for the use of thinner photovoltaic absorber layers in the fabrication of solar panels. This results in less material being need for production of photovoltaic devices of similar absorptive power, further resulting in less expensive/more efficient cells.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. A photo voltaic cell including silicon which has been modified such that its optical properties are changed, whereby it exhibits an absorption coefficient which is greatest at frequencies corresponding more closely to the range of the peak frequencies in the solar spectrum than that of unmodified silicon.

2. The photo voltaic cell of claim 1 wherein the silicon of the cell has been processed such that a significant portion of said silicon is converted to the meta stable form of silicon having the R8 (rhombohedral unit cell) structure.

3. The photo voltaic cell of claim 1 wherein said silicon contains boron and arsenic atoms implanted in equal amounts as substitutional impurities into said silicon at the few percents level.

4. A method for increasing the photo absorption efficiency of silicon used in a photovoltaic cell comprising the step of implanting impurities at a few percent level into said silicon.

5. The method of claim 4 wherein the impurity is one of boron or arsenic.

6. The method of claim 5 wherein both boron and arsenic are implanted into said silicon.

7. The method of claim 6 wherein both said boron and arsenic impurities are implanted in equal amounts.

8. A method for increasing the photo absorption efficiency of silicon used in a photovoltaic cell comprising the step of changing the optical properties of said silicon whereby it exhibits an absorption coefficient which is greatest at frequencies which overlaps with the range of peak frequencies in the solar spectrum.

9. The method of claim 8 wherein the step of changing the optical properties of said silicon comprises the changing of its structure to the rhombohedral R8 form.

10. The method of claim 9 wherein the rhombohedral R8 form of said silicon is obtained by pressure induced crystallization using an indenter.
